(19) United States
(12) Patent Application Publication
(10) Pub. No.: US 2024/0389272 A1
(43) Pub. Date: Nov. 21, 2024

(54) METHOD FOR PRODUCING A HEAT SINK

(71) Applicant: PHOENIX CONTACT GMBH & CO. KG, Blomberg (DE)

(72) Inventors: Fabio Welslau, Lemgo (DE); Helmut Eusterholz, Paderborn (DE)

(21) Appl. No.: 18/690,783

(22) PCT Filed: Sep. 14, 2022
(86) PCT No.: PCT/EP2022/075506

§ 371 Date: Mar. 11, 2024

(30) Foreign Application Priority Data
Sep. 23, 2021 (LU) LU500679

(51) Int. Cl. H05K 7/20

(52) U.S. Cl. CPC H05K 7/20418

(57) ABSTRACT

A workpiece set includes: a supporting structure; and a blank of a heat sink for fitting in place in the supporting structure. The supporting structure has an inner dimension for receiving the blank of the heat sink in a received state. The blank of the heat sink includes: a heat sink base for thermally contacting an electrical component on a printed circuit board, which is anchored or anchorable in the supporting structure, and a plurality of fins, which in the received state have an extent in a direction of the inner dimension, at least one first fin of the plurality of fins extending over a first dimension from the heat sink base in a first direction, and at least one second fin of the plurality of fins extending over a second dimension from the heat sink base in a second direction opposite the first direction.

### CROSS-REFERENCE TO PRIOR APPLICATIONS

This application is a U.S. National Phase application under 35 U.S.C. § 371 of International Application No. PCT/EP2022/075506, filed on Sep. 14, 2022, and claims benefit to Luxembourg Patent Application No. LU 500679, filed on Sep. 23, 2021. The International Application was published in German on Mar. 30, 2023 as WO/2023/046548 under PCT Article 21 (2).

### FIELD

The invention relates to a method for producing a heat sink. In particular, without being limited thereto, a workpiece set and a production method are disclosed.

### BACKGROUND

In the prior art, for example the modular system 10 described in document WO 2019/219695 A1 for producing an electronic device, a heat sink 15 has a mechanical connection to a supporting structure 11 (e.g., a housing) of a printed circuit board 17. The mechanical connection defines the relative position of the heat sink 15 in the system consisting of the supporting structure 11, the printed circuit board 17 and the component 16 (also: the part) to be cooled. The position of the heat sink base contacting the component 16 is thus also defined.

In order to thermally connect components 16 of different heights to the heat sink 15, the heat sink base must be modified during production. This is done either subtractively, for example by milling out portions as shown in FIG. 1, or additively, for example by applying spacer elements as shown in FIG. 2.

The maximum possible variance of the height of the component 16 is therefore limited in the prior art. This is because in order to install high components 16, the heat sink base must be very thick (as in the example of FIG. 1) and/or within the supporting structure 11 can be positioned far away from the printed circuit board 17. As a result, for flat components 16 an unnecessarily large space, which can serve as a flow channel, for example, is installed with a thick heat sink base (as in the example of FIG. 2). In addition, the device is thereby heavier.

Furthermore, the production of the heat sink is complicated, because the heat sink base has to be adapted not only to the height of the component but also to the size and shape of the surface of the component.

### SUMMARY

In an embodiment, the present invention provides a workpiece set, comprising: a supporting structure: and a blank of a heat sink configured to fit in place in the supporting structure, wherein the supporting structure has an inner dimension configured to receive the blank of the heat sink in a received state, wherein the blank of the heat sink comprises: a heat sink base configured to thermally contact an electrical component on a printed circuit board, which is anchored or anchorable in the supporting structure, and a plurality of fins, which in the received state have an extent in a direction of the inner dimension, at least one first fin of the plurality of fins extending over a first dimension from the heat sink base in a first direction, and at least one second fin of the plurality of fins extending over a second dimension from the heat sink base in a second direction opposite the first direction, an overall dimension of the blank corresponding to a sum of the first dimension and of the second dimension and being greater than the inner dimension, and wherein, to fit the blank in place, the plurality fins are shortened or shortenable such that the sum of the first dimension and of the second dimension corresponds to the inner dimension of the supporting structure and the first dimension or the second dimension defines a position of the heat sink base within the supporting structure.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows a first reference example of a modular system for producing an electronic device according to the prior art;

FIG. 2 shows a second reference example of a modular system for producing an electronic device according to the prior art;

shows a schematic sectional view of a workpiece set according to an FIG. 3 exemplary embodiment;

FIG. 4 shows a schematic diagram of the first dimension and of the second dimension for fitting a blank of the workpiece set in place in a given supporting structure for a given height of the component;

FIG. 5 shows a schematic sectional view of four different arrangements of the workpiece set according to the exemplary embodiment in FIG. 3 for producing heat sinks for three different heights of the component;

FIG. 6 shows schematic representations of the fitting in place starting from a uniform blank of the workpiece set for producing heat sinks for three different heights of the component; and

FIG. 7 shows schematic representations of the heat sink as a fitted blank received in the supporting structure for three different heights of the component according to FIG. 6.

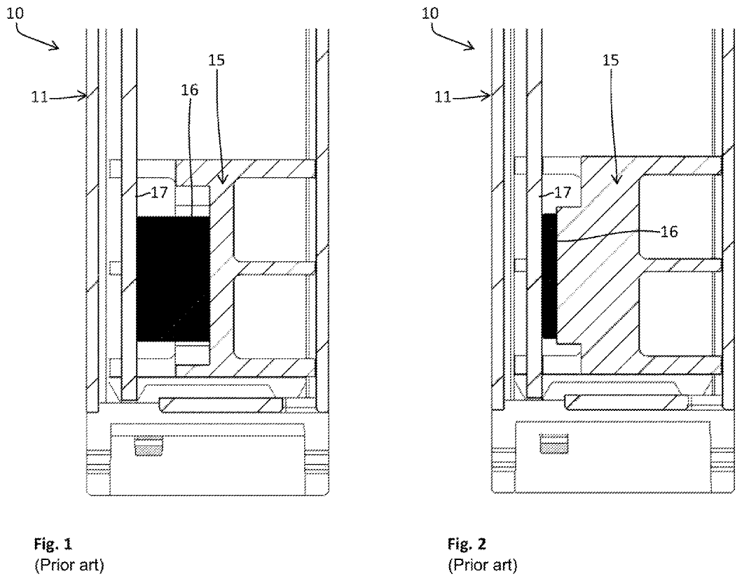

### DETAILED DESCRIPTION

In an embodiment, the present invention provides a method which can adapt a heat sink for components of different heights with less production effort. In an embodiment, the invention provides a heat sink for varying supporting structures and/or varying components, which heat sink makes better use of the installation space, in particular for convective cooling.

Exemplary embodiments of the invention are described below with partial reference to the figures.

According to a first aspect, a workpiece set comprises a supporting structure and a blank of a heat sink for fitting in place in the supporting structure. The supporting structure has an internal dimension for receiving the inserted heat sink. The blank of the heat sink comprises a heat sink base which is designed to thermally contact an electrical component on a printed circuit board that is anchored or can be anchored in the supporting structure. Furthermore, the blank of the heat sink comprises a plurality of fins which, in the received state, have an expansion in the direction of the inner dimension (e.g., extend completely or in portions parallel to the inner dimension or are angled in portions relative to the direction of the inner dimension). At least one first fin of the fins extends (for example, not necessarily in a straight line) over a first dimension of the heat sink base in a first direction. At least one second fin of the fins extends (for example not necessarily in a straight line) over a second dimension from the heat sink base in a second direction opposite the first direction. An overall dimension of the blank corresponds to the sum of the first dimension and the second dimension and is greater than the inner dimension of the supporting structure. To fit the blank in place, the fins are shortened or can be shortened such that the sum of the first dimension and the second dimension corresponds to the inner dimension of the supporting structure and the first dimension and/or the second dimension defines a position of the heat sink base within the supporting structure.

Exemplary embodiments of the workpiece set make it possible for the position of the heat sink base of the heat sink in the overall system of the supporting structure and of the printed circuit board, for example starting from the same blank, i.e., a non-component-specific blank, to be adapted to the varying requirements of components of different heights and/or of different internal dimensions.

Exemplary embodiments of the workpiece set make possible a versatile use of uniform blanks due to the possibility of optionally rotating the blank 180° when fitting it in place in the supporting structure (i.e., based on an optional assignment as to which sides of the supporting structure correspond to the first direction and the second direction), and the possibility of shortening in the first direction (i.e., on a first side) and/or in the second direction (i.e., on a second side).

The position of the heat sink base can be defined by the first dimension and/or the second dimension. For example, the position of the heat sink base within the supporting structure can be defined in the received state by the first dimension, by the second dimension or by the difference between the first dimension and the second dimension. For example, with a central position of the heat sink base within the supporting structure, the difference is equal to zero.

In the received state, a free end of the at least one first fin can rest against the supporting structure on the inside or be anchored in a positive-locking manner. The position of the heat sink base within the supporting structure in the received state can thereby be defined by the first dimension. Alternatively or additionally, a free end of the at least one second fin can rest against the supporting structure on the inside or be anchored in a positive-locking manner. The position of the heat sink base within the supporting structure in the received state can thereby be defined by the second dimension. For example, the free end of the at least one first fin and the free end of the at least one second fin can bear against the supporting structure on the inside, so that, due to the first and second directions being opposite one another, the heat sink (at least in the direction of the fins extending from the heat sink base) is arranged in a positive-locking manner in the supporting structure.

The position of the heat sink base can in the received state correspond to a position of the electrical component within the supporting structure.

The dimensions can each comprise a length dimension. Alternatively or additionally, the inner dimension of the supporting structure can correspond to an internal dimension of a free space in the supporting structure. The free space can be designed to receive the heat sink, i.e., the inserted blank of the heat sink, for example along a transverse direction.

The first direction and the second direction can be opposite one another (also: antiparallel, i.e., parallel and oppositely aligned). The first direction and the second direction can be parallel to the inner dimension (for example in the received state).

The heat sink base can be designed to thermally contact an electrical component in order to absorb waste heat. The thermal contact can be a direct mechanical contact or an indirect mechanical contact via a thermal bridge. Alternatively or additionally, the heat sink base can contact the electrical component directly or indirectly, for example via a heat-conducting material (also in technical terminology, thermal interface material or TIM). Alternatively or additionally, the heat sink base can thermally contact the electrical component via the printed circuit board. For example, the heat sink base can directly contact the printed circuit board, wherein the electrical component is arranged on a side of the printed circuit board facing away from the heat sink base.

The electrical component can face the heat sink on the printed circuit board that is anchored or can be anchored in the supporting structure.

The plurality of fins may extend perpendicularly to the heat sink base.

The shortened first dimension and/or the shortened second dimension can be a function of the inner dimension of the supporting structure and/or a height of the component in order to fit the heat sink in place.

The blank of the heat sink can furthermore comprise a web connecting the fins in a transverse direction.

The transverse direction can be transverse, preferably perpendicular, to the first and second directions. Alternatively or additionally, the transverse direction can be transverse, preferably perpendicular, to the longitudinal direction.

The heat sink base can be parallel to the longitudinal direction and transverse direction.

The heat sink base can comprise a surface of the web.

The surface of the web can be exposed to the first direction and/or to the second direction.

The web and adjacent second fins can form or enclose (for example, border) a flow channel in the supporting structure.

The flow channel can be designed for convective cooling of the component. For example, air can flow counter to the gravitational direction (i.e., due to a chimney effect) within the flow channel due to a temperature gradient. Because the width of the web does not have to be adapted to the component, the width of the web can be smaller (for example compared to conventional blanks or heat sinks for flat components) and/or the cross-section of the flow channel can be larger.

The web and/or the heat sink base can be arranged symmetrically in the blank or in the inserted heat sink with respect to the first direction and the second direction.

Alternatively, the web and/or the heat sink base can be arranged in the blank asymmetrically with respect to the first direction and the second direction. By a rotation by 180 degrees (180°), the first direction and the second direction can be exchangeable, for example for minimizing or preventing the shortening of the first dimension and/or for minimizing or preventing the shortening of the second dimension.

In the received state, the heat sink base of the heat sink can extend transversely, preferably perpendicularly, to the inner dimension of the supporting structure. Alternatively or additionally, the plurality of fins can extend transversely, preferably perpendicularly, to the heat sink base.

The fins can be arranged at a distance from one another (for example equidistantly) on the heat sink base.

The heat sink base of the heat sink can comprise a flat surface of the blank. The heat sink base of the inserted blank (i.e., of the heat sink) can correspond to the heat sink base of the blank unchanged or unprocessed.

The heat sink base of the inserted heat sink can correspond unchanged to the heat sink base of the blank.

Alternatively, the heat sink base of the inserted heat sink can be modified relative to the heat sink base of the blank by cutting (i.e., machining) or additively.

The supporting structure (for example the clearance) can furthermore have a second inner dimension in the transverse direction. The blank and/or the heat sink can have a second overall dimension in the transverse direction. The second overall dimension of the blank and/or of the heat sink can be smaller than or equal to the second inner dimension of the supporting structure.

The supporting structure can be or comprise a housing.

The shortening of the plurality of fins (for example the at least one first fin and/or the at least one second fin) can comprise cutting (optionally milling) and/or punching.

The blank can be metallic and/or integrally monolithic. The blank can comprise aluminum or copper.

The first direction and the second direction opposite the first direction can be transverse, preferably perpendicular, to a longitudinal direction of the blank.

The first dimension can be a maximum of a profile of the shortened at least one first fin in the first direction along a longitudinal direction of the heat sink. Alternatively or additionally, the second dimension can be a maximum of a profile of the shortened at least one second fin in the second direction along a longitudinal direction of the heat sink (150).

Alternatively or additionally, the at least one shortened first fin (for example each of the at least one shortened first fins) can have a profile along a longitudinal direction of the heat sink. The first dimension can correspond to a projection of the profile and/or a maximum of the first dimension in the profile.

Alternatively or additionally, the at least one shortened second fin (for example every second fin) can have a profile along a longitudinal direction of the heat sink. The second dimension can correspond to a projection of the profile or a maximum of the second dimension in the profile.

The heat sink base can comprise a minimum of the profile of the shortened at least one first fin in the first direction along the longitudinal direction of the heat sink.

Alternatively or additionally, the at least one shortened first fin (for example every first fin) can have a profile along a longitudinal direction of the heat sink. The heat sink base can correspond to a recess of the profile and/or a minimum of the first dimension in the profile.

The blank can be produced in the longitudinal direction by extrusion, preferably extrusion molding.

The direction of the extrusion molding can be a longitudinal direction of the blank. The first direction and the opposite second direction of the fins can be transverse, preferably perpendicular, to a longitudinal direction of the extrusion and/or of the blank.

A shape of the heat sink base and/or of the blank and/or of the (unshortened) fins of the blank can correspond to a die of the extrusion molding. The extrusion molding can also be referred to as extrusion.

A second aspect comprises a method for producing a heat sink.

The method for production (in short: production method) of the heat sink comprises a step of providing (i.e., provision of) a supporting structure which has an internal dimension for receiving the heat sink.

The method further comprises a step of providing (i.e., provision of) a blank of the heat sink. The blank comprises a heat sink base which is designed to thermally contact an electrical component on a printed circuit board that is anchored or can be anchored in the supporting structure, and a plurality of fins which, in the received state, have an extension in the direction of the inner dimension. At least one first fin of the fins extends over a first dimension from the heat sink base in a first direction. At least one second fin of the fins extends over a second dimension from the heat sink base in a second direction opposite the first direction. An overall dimension of the blank corresponds to the sum of the first dimension and the second dimension and is greater than the inner dimension.

The method further comprises a step of fitting the blank in place, wherein the fins are shortened such that the sum of the first dimension and of the second dimension corresponds to the inner dimension of the supporting structure and the first dimension or the second dimension defines a position of the heat sink base within the supporting structure.

The method of the second aspect can be carried out by means of the workpiece set of the first aspect. The manufacturing method can comprise any feature and/or any method step disclosed herein in the context of the workpiece set. Alternatively or additionally, the workpiece set can comprise any feature which is explicitly or implicitly disclosed in the context of the production method.

FIG. 3 shows a schematic sectional view of a workpiece set generally designated by reference number 100 according to an exemplary embodiment.

The workpiece set 100 comprises a supporting structure 110 and a blank 130 of a heat sink for fitting in place in the supporting structure 110.

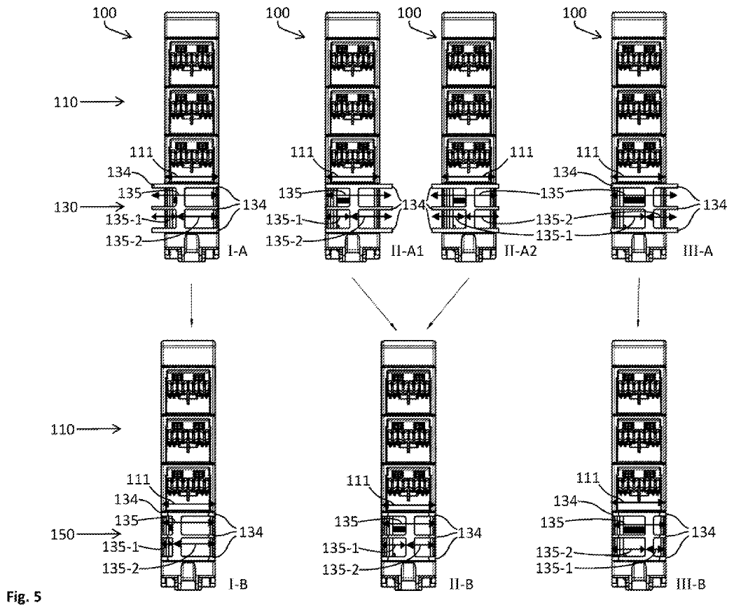

The heat sink, i.e., the inserted blank 130, is hereinafter generally referred to by reference number 150. Exemplary embodiments of the heat sink 150 are shown in FIGS. 5, 6 and 7.

The supporting structure 110 has an inner dimension 111 for receiving the inserted heat sink 150. To compare the dimensions, the blank 130 is superimposed on the supporting structure 110. It can thereby be seen that an overall dimension 135 of the blank 130 in a fin direction 136 is greater than the inner dimension 111 of the supporting structure 110.

The blank 130 of the heat sink 150 comprises a heat sink base 132 which is capable of thermally contacting an electrical component 160. The electrical component 160 (for example a discrete electronic component or an integrated circuit) can be arranged (e.g., soldered) on a printed circuit board 170 that is anchored or can be anchored in the supporting structure 110. The printed circuit board 170 can be anchored or can be anchorable between a contact surface and a latching lug 112 of the supporting structure 110.

Furthermore, the blank 130 of the heat sink 150 comprises a plurality of fins 134. When the inserted blank 130 is received in the supporting structure 110, the fins 130 have an extension in the direction of the inner dimension 111. For example, the fins 130 extend parallel to the inner dimension 111.

At least one first fin 134-1 of the fins 134 extends (not necessarily in a straight line) over a first dimension 135-1 from the heat sink base 132 in a first direction 136-1. That is to say, the extent of the first fin 134-1 measured in the direction of the inner dimension 111 and relative to the heat sink base 132 (as the zero point) results in the first dimension 135-1. At least one second fin 134-2 of the fins 134 extends (not necessarily in a straight line) over a second dimension 135-2 from the heat sink base 132 in a second direction 136-2 opposite the first direction 136-1. That is to say, the extent of the second fin 134-2 measured in the direction of the inner dimension 111 and relative to the heat sink base 132 (as the zero point) results in the second dimension 135-2.

The overall dimension 135 of the blank 130 corresponds to the sum of the first dimension 135-1 and the second dimension 135-2. The overall dimension 135 is greater than the inner dimension 111.

To fit the blank 130 in place, the fins 134 are shortened or can be shortened such that the sum of the first dimension 135-1 and of the second dimension 135-2 corresponds to the inner dimension 111 of the supporting structure 110. Furthermore, the first dimension 135-1 and/or the second dimension 135-2 defines a position of the heat sink base 132 within the supporting structure 110.

Exemplary embodiments of the workpiece set 100 make it possible to produce differently shaped heat sinks 150 starting from the same blank 130. The heat sink base 132 can be formed already in the blank 130. For example, the processing or fitting of the blank 130 in place can be limited to the shortening of the fins 134.

The heat sink 150, i.e., the result of fitting the blank 130 in place, can be accommodated in a positive-locking manner in the supporting structure 110 (for example a housing) of a given width due to the corresponding shortened overall dimension.

The blank 130 has a web 138 and fins 134-1 or 134-2 projecting to one another on both sides of the web 138 (preferably parallel). Due to the shortening of the lengths 135-1 and 135-2 (i.e., of the first or second dimension) of the fins 134-1 or 134-2 on both sides (i.e., in the first direction 136-1 and in the second direction 136-2), in production there are two degrees of freedom with respect to the heat sink base 132.

The second dimension 135-2 can comprise a width 139 of the web 138.

A first degree of freedom, which corresponds to the sum 135 of the dimensions 135-1 and 135-2 of the fins 134 (shortened after the fitting in place), is defined by the given inner dimension 111 of the supporting structure 110 (for example the given width of the housing 110).

The remaining second degree of freedom of the production allows the heat sink base 132 (for example the web 138) to be positioned within the inner dimension 111 of the supporting structure 110 (for example within the width of the housing 110) in such a way that the heat sink base 132 (preferably unprocessed compared to the blank 130) is able to contact the component 160 depending on (i.e., adapted to) a height 161 of the component 160 for heat dissipation.

While the first aspect of the workpiece set 100 is described here, the person

skilled in the art will always read corresponding features or method steps of the second aspect of the production method. For example, the blank 130 is preferably produced by extrusion (for example, extrusion molding). Alternatively or additionally, the fins 134 are shortened and/or the web 138 is exposed in portions to the first direction 136-1 for thermal contact with the component 160 (i.e., on the heat sink base 132) preferably in a milling process.

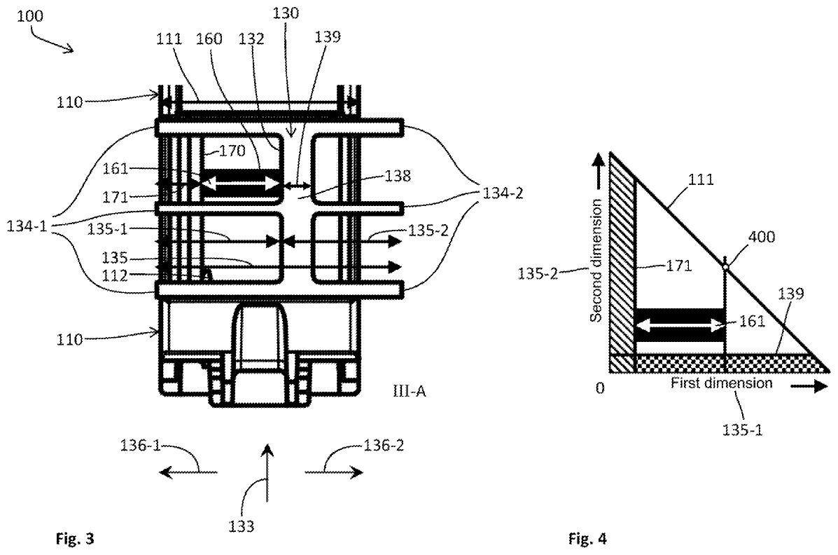

FIG. 4 shows a schematic diagram of the two degrees of freedom in the production of the heat sink 150 starting from the blank 130. The two degrees of freedom correspond to the two-dimensional plane of FIG. 4. This plane is spanned by the first dimension 135-1 and by the second dimension 135-2.

Optionally, the position 171 of the printed circuit board 170 (measured from the free end of the shortened at least one first fin 134-1) limits the first dimension 135-1. Alternatively or additionally, the width 139 of the web 138 limits the second dimension 135-2.

The inner dimension 111 of the supporting structure 110 is determined by the sum of the first dimension 135-1 and of 135-2, which corresponds to a diagonal in the diagram in FIG. 4. The point of intersection 400 depends on the height 161 of the component 160. The shortened first dimension 135-1 and the shortened second dimension 135-2 of the first fins 134-1 or of the second fins 134-2 of the heat sink 150 are fixed at the intersection point 400.

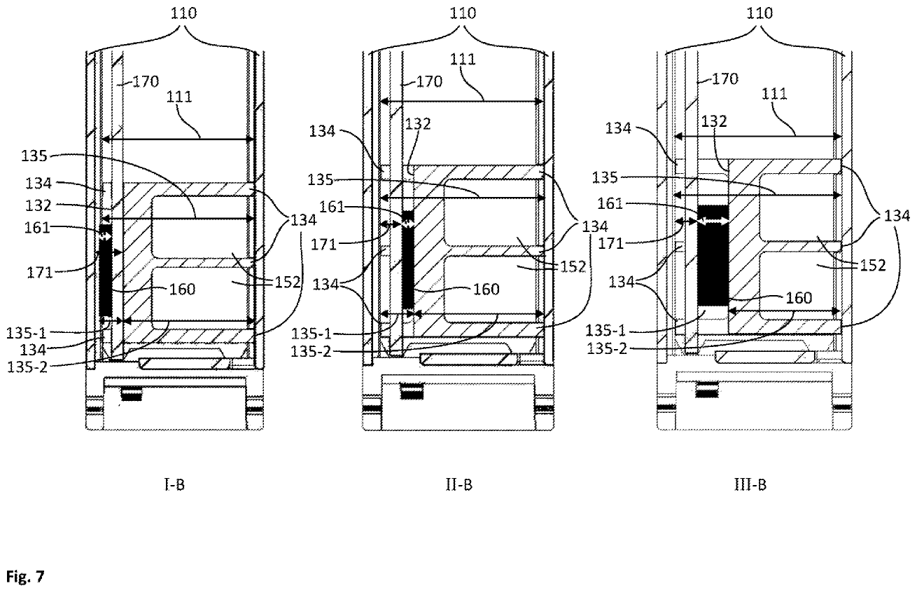

In each exemplary embodiment, the shortened fins 134 can serve for the mechanical connection (for example, by positive-locking contact or clamping or latching) within the supporting structure 110. Alternatively or additionally, the fins 134 can serve to support the printed circuit board 170 carrying the component 160. Alternatively or additionally, the shortened fins can serve as cooling fins. Alternatively or additionally, the shortened fins can serve as a wall of a flow channel (denoted generally by reference character 152). Exemplary embodiments of the flow channel are shown in FIG. 7.

FIG. 5 is a schematic sectional view of four different arrangements I-A, II-A1, II-A2 and III-A of the workpiece set 100 according to the exemplary embodiment in FIG. 3 for producing heat sinks 150 for three different heights 161 of the component 160.

Resulting devices, i.e., generally the supporting structure 110 and the heat sinks 150 accommodated in the supporting structure 110, are shown in the sub-figures I-B, II-B and III-B in FIG. 5.

The shortened first dimension 135-1 and the shortened second dimension 135-2 for fitting the heat sink 150 in place, for example the point of intersection 400, is thus a function of the inner dimension 111 of the supporting structure 110 and the height 161 of the component 160.

As shown with reference to the arrangements II-A1 and II-A2, there can be two solutions for fitting in place starting from the same blank 130 which differ in a rotation of the blank 180° about an axis of the longitudinal direction 131 of the blank 130. In other words, the at least one first fin 134-1 and the at least one second fin 134-2 can be switched.

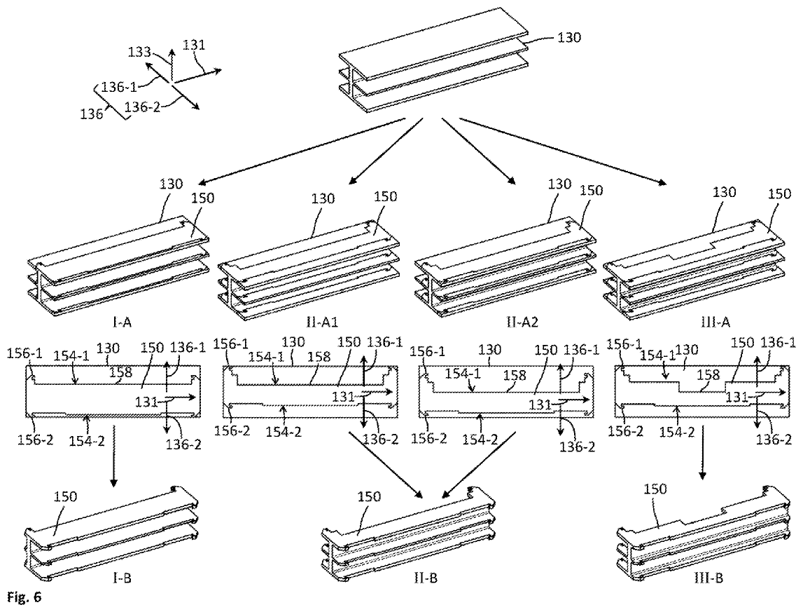

FIG. 6 shows schematic representations of the fitting in place starting from a uniform blank 110 of the workpiece set 100 for producing heat sinks 150 for three different heights 161 of the component 160, for example according to FIG. 5.

As shown schematically in the plan view within FIG. 6 (i.e., in the plane of the directions 131 and 136), the heat sink base 132 can correspond to a surface of the web 138 in a portion along the longitudinal direction 131 (for example, with reference character 158).

Alternatively or additionally, the shortened at least one first fin 134-1 and/or the shortened at least one second fin 134-2 can have a profile 154-1 or 154-2 along the longitudinal direction 131.

The first dimension 135-1 may be a maximum 156-1 of the profile 154-1 of the shortened at least one first fin 134-1 in the first direction 136-1. Alternatively or additionally, the second dimension (135-2) can be a maximum 156-2 of the profile 154-2 of the shortened at least one second fin 134-2.

The heat sink base 132 can correspond to a minimum 158 of the profile 154 of the shortened at least one first fin 134-1 in the first direction 136-1 along the longitudinal direction 131 (i.e., a minimum of the length in the first direction 136-1 as a function of the longitudinal direction 131). At the minimum 158, the length of the first fin 134-1 in the first direction 136-1 can be zero, i.e., flush with the surface of the web 138 comprising the heat sink base 132.

FIG. 7 shows schematic representations of the heat sink 150 (as a fitted blank 130) accommodated in the supporting structure 110 for three different heights of the component 160, for example according to FIG. 6.

The web 138 and adjacent second fins 134-2 can form or enclose a flow channel 152 in the supporting structure 110. The flow channel can be designed for convective cooling of the component 160 (for example passive or by means of a fan).

In the exemplary embodiment of the heat sink 150 shown in Fig. I-B, the heat sink base 132 contacts the printed circuit board 170. The height 161 of the component is less than or equal to the first dimension 135-1. Alternatively or additionally, the height 161 of the component is less than or equal to the position 171 of the printed circuit board 170.

An exemplary embodiment of the method for producing a heat sink 150 comprises a step of providing a supporting structure 110. The supporting structure 110 has an inner dimension 111 for receiving the heat sink 150.

The method further comprises a step of providing a blank 130 of the heat sink 150. The blank 130 comprises a heat sink base 132 which is designed to thermally contact an electrical component 160 on a printed circuit board 170 that is anchored or can be anchored 112 in the supporting structure 110. Furthermore, the provided blank comprises a plurality of fins 134 which, in the received state, have an extension in the direction of the inner dimension 111 (for example, in the received state extend parallel to the inner dimension 111). At least one first fin 134-1 of the fins 134 extends by a first dimension 135-1 from the heat sink base 132 in a first direction 136-1. At least one second fin 134-2 of the fins 134 extends by a second dimension 135-2 from the heat sink base 132 in a second direction 136-2 opposite the first direction 136-1. An overall dimension 135 of the provided blank 130 corresponds to the sum of the first dimension 135-1 and the second dimension 135-2 and is greater than the inner dimension 111.

The method further comprises a step of fitting the blank 130 in place. The fins 134 are shortened in such a way that the sum of the first dimension 135-1 and of the second dimension 135-2 corresponds to the inner dimension 111 of the supporting structure 110, and the first dimension 135-1 and/or the second dimension 135-2 defines a position of the heat sink base 132 within the supporting structure 110.

In each exemplary embodiment of the workpiece set 100 and/or of the method, the blank 130 of the heat sink 150 (produced for example by extrusion) can be designed to be overlarge (e.g., too high) according to the overall dimension 135 compared to the inner dimension 111. For example, material is symmetrically available on the fins 134 for shortening.

During the production of the heat sink 150, preferably during the finishing of the blank 130 (preferably by milling), the position of the heat sink base 132 relative to the mechanical connection is defined via the fins 134 (i.e., the first and/or second dimension). During this process, the position can be adapted (also: calibrated) to the corresponding application (for example height 161).

In a system comprising the supporting structure 110 (for example a housing), the printed circuit board 170 and the heat sink 150, the printed circuit board 170 has a fixed position relative to the supporting structure 110 (for example to the housing). The overall dimension 135 of the heat sink 130 (i.e., the heat sink height) correlates with the housing width: namely, it corresponds to the inner dimension 111 of the supporting structure 110. In order to adjust the position of the heat sink base 132 application-specifically, the fins 134 are designed such that the overall dimension 135 of the blank 130 is greater than the inner dimension 111 (for example the housing width). For positioning the heat sink base 132 relative to the printed circuit board 170 (for example a TOP side of the printed circuit board 170), the fins 134 are shortened (preferably by milling) so that the heat sink height 135 corresponds to the housing width 111.

Depending on the requirements, the heat sink base 132 or the web 138 can be positioned closer to or further away from the printed circuit board 170. The projection relative to the supporting structure 110 is removed by the finishing of the blank 130.

As can be seen from the above exemplary embodiments, the blank (for example an extrusion profile) can be used for different distances between the heat sink base and the printed circuit board (PCB). Because the blank 130 is in principle mechanically reworked, for example for mechanical connection, for thermal connection and/or for mounting force elements (for example springs), the shortening (for example, post-milling) of the fins 134 is of little economic importance when producing the heat sink.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

Conventional electrical device 10

### Housing 11

Conventional heat sink 15

### Component 16

Printed circuit board 17

### Workpiece set 100

Supporting structure, for example housing 110
Inner dimension of the supporting structure 111
Blank of a heat sink 130
Longitudinal direction of the blank or of the heat sink 131
Heat sink base of the blank or of the heat sink 132
Transverse direction 133
Fins of the blank or of the heat sink 134
At least one first fin of the fins of the heat sink 134-1
At least one second fin of the fins of the heat sink 134-2
Overall dimension of the fins extending from the heat sink base 135
First dimension of the first fin extending from the heat sink base 135-1
Second dimension of the second fin extending from the heat sink base 135-2
Direction of the fins extending from the heat sink base (i.e., the first or the second direction), in short: fin direction 136
First direction of the first fins extending from the heat sink base 136-1
Second direction of the second fins extending from the heat sink base 136-2
Web of the blank or of the heat sink 138
Width of the web in the fin direction 139
Heat sink, i.e., blank fitted in place in the supporting structure 150
Flow channel 152
Profile of the at least one first fin 154-1
Profile of the at least one second fin 154-2
Maximum of the profile of the at least one first fin 156-1
Maximum of the profile of the at least one second fin 156-2
Minimum of the profile of the at least one first fin 158

### Component 160

Height of component 161
Printed circuit board 170
Position of the printed circuit board 171
Point of intersection in the diagram of the first and second dimensions 400

1. A workpiece set, comprising:
a supporting structure; and
a blank of a heat sink configured to fit in place in the supporting structure,
wherein the supporting structure has an inner dimension configured to receive the blank of the heat sink in a received state,
wherein the blank of the heat sink comprises:
a heat sink base configured to thermally contact an electrical component on a printed circuit board, which is anchored or anchorable in the supporting structure, and
a plurality of fins, which in the received state have an extent in a direction of the inner dimension, at least one first fin of the plurality of fins extending over a first dimension from the heat sink base in a first direction, and at least one second fin of the plurality of fins extending over a second dimension from the heat sink base in a second direction opposite the first direction, an overall dimension of the blank corresponding to a sum of the first dimension and of the second dimension and is being greater than the inner dimension, and
wherein, to fit the blank in place, the plurality fins are shortened or shortenable such that the sum of the first dimension and of the second dimension corresponds to the inner dimension of the supporting structure and the first dimension or the second dimension defines a position of the heat sink base within the supporting structure.

2. The workpiece set of claim 1, wherein a shortened first dimension or a shortened second dimension for fitting the heat sink in place is a function of a height of the electrical component.

3. The workpiece set of claim 1, wherein the blank of the heat sink comprises:
a web connecting the fins in a transverse direction.

4. The workpiece set of claim 3, wherein the web and adjacent second fins of the plurality of fins form or enclose a flow channel in the supporting structure.

5. The workpiece set of claim 3, wherein the web is arranged symmetrically in the blank or in the heat sink with respect to the first direction and the second direction, or
wherein the web is arranged asymmetrically with respect to the first direction and to the second direction in the blank, and by a rotation of 180 degrees the first direction and the second direction are exchangeable for minimizing or preventing a shortening of the first dimension and/or of the second dimension.

6. The workpiece set of claim 1, wherein the heat sink base of the heat sink extends transversely to the inner dimension of the supporting structure in the received state, and/or
wherein the plurality of fins extend transversely to the heat sink base.

7. The workpiece set of claim 1, wherein the heat sink base of the heat sink corresponds unchanged to the heat sink base of the blank, or
wherein the heat sink base of the heat sink is machined or additively processed in relation to the heat sink base of the blank.

8. The workpiece set of claim 1, wherein the supporting structure comprises a housing.

9. The workpiece set of claim 1, wherein a shortening of the plurality of fins comprises cutting.

10. The workpiece set of claim 1, wherein the blank of the heat sink is metallic and/or integrally monolithic.

11. The workpiece set of claim 1, wherein the first direction and the second direction opposite the first direction are transverse to a longitudinal direction of the blank of the heat sink.

12. The workpiece set of claim 1, wherein at least one shortened first fin of the plurality of fins has a profile along a longitudinal direction of the heat sink, and the first dimension corresponds to a projection of the profile or to a maximum of the first dimension in the profile, and/or
wherein at least one shortened second fin of the plurality of fins has a profile along a longitudinal direction of the heat sink, and the second dimension corresponds to a projection of the profile or a maximum of the second dimension in the profile.

13. The workpiece set of claim 1, wherein at least one shortened first fin of the plurality of fins has a profile along a longitudinal direction of the heat sink, and
wherein the heat sink base corresponds to an indentation of the profile or to a minimum of the first dimension in the profile.

14. The workpiece set of claim 1, wherein the blank of the heat sink is produced in a longitudinal direction by extrusion.

15. A method for producing a heat sink, the method comprising:
providing a supporting structure which has an inner dimension configured to receive the heat sink;
providing a blank of the heat sink, wherein the blank of the heat sink comprising a heat sink base configured to thermally contact an electrical component on a printed circuit board that is anchored or anchorable in the supporting structure, and a plurality of fins which, in a received state of the blank of the heat sink, have an extent in a direction of the inner dimension, at least one first fin of the plurality of fins extending over a first dimension from the heat sink base in a first direction, and at least one second fin of the plurality of fins extending over a second dimension from the heat sink base in a second direction opposite the first direction, an overall dimension of the blank of the heat sink corresponding to a sum of the first dimension and of the second dimension and being greater than the inner dimension; and
fitting the blank of the heat sink in place, the plurality of fins being shortened such that the sum of the first dimension and of the second dimension corresponds to the inner dimension of the supporting structure, and the first dimension or the second dimension defines a position of the heat sink base within the supporting structure.

16. The workpiece set of claim 3, wherein the heat sink base comprises a surface of the web.

17. The workpiece set of claim 6, wherein the heat sink base of the heat sink extends perpendicularly to the inner dimension of the supporting structure in the received state, and/or
wherein the plurality of fins extend preferably perpendicularly to the heat sink base.

18. The workpiece set of claim 9, wherein the shortening of the plurality of fins comprises milling and/or punching.

19. The workpiece set of claim 11, wherein the first direction and the second direction opposite the first direction are perpendicular to the longitudinal direction of the blank of the heat sink.

20. The workpiece set of claim 14, wherein the extrusion comprises extrusion molding.
